(19) United States
(12) Patent Application Publication
(10) Pub. No.: US 2008/0054943 A1
(43) Pub. Date: Mar. 6, 2008

(54) Variable switching point circuit

(76) Inventors: Ravindraraj Ramaraju, Round Rock, TX (US); Kenneth R. Burch, Austin, TX (US); Prashant U. Kenkare, Austin, TX (US); William C. Moyer, Dripping Springs, TX (US)

Correspondence Address: HAMILTON & TERRILE, LLP, P.O. BOX 203518, AUSTIN, TX, 78720, US

(21) Appl. No.: 11/470,342

(22) Filed: Sep. 6, 2006

(51) Int. Cl. H03K 19/094

(52) U.S. Cl. 326/83

(57) ABSTRACT

A variable switching point inverter (30) is disclosed which lowers the threshold voltage lowered for both rising and falling edge input voltages (V_{IN}) by changing the P/N ratio of the inverter based on the delayed output state (V_{OUT}) of the inverter. The variable switching point inverter may be constructed as a CMOS integrated circuit with a first inverter stage (33, 34) coupled in parallel to a second inverter stage (35, 36) having extra PMOS (37) and NMOS (38) transistors connected to V_{DD} and V_{SS}, respectively, where the extra PMOS and NMOS transistors are controlled by the delayed output signal (40) generated by a delay element (39) coupled to the output of the first inverter stage. By using a delayed feed back signal (40) to control the extra PMOS and NMOS gates (37, 38), the switching point voltage of the first inverter stage (33, 34) is altered, depending on whether the input transitions are high-to-low or low-to-high.

### BACKGROUND OF THE INVENTION

1. Field of the Invention

The present invention relates in general to the field of electric circuits. In one aspect, the present invention relates to high speed complementary metal oxide silicon (“CMOS”) circuits.

2. Description of the Related Art

The CMOS inverter is a basic building block for digital circuit design which performs the logic operation of converting a “1” input to a “0” output, and vice versa. When the input to the inverter is connected to ground (or “0” or “low”), the inverter output is pulled to Vdd through a PMOS device that has its gate connected to the input and that is source-drain connected between Vdd and the output node. When the input to the inverter is connected to V_{DD} (or “1” or “high”), the inverter output is pulled to ground through an NMOS device that has its gate connected to the input and that is source-drain connected between ground and the output node. This operation is illustrated with the transfer characteristic curves depicted in FIG. 1 for three different CMOS inverter circuits. In particular, curve 10 illustrates the transfer characteristic for an inverter having a transconductance ratio (βₙ/βₚ)=1, curve 12 illustrates the transfer characteristic for an inverter having a transconductance ratio (βₙ/βₚ)<1, and curve 14 illustrates the transfer characteristic for an inverter having a transconductance ratio (βₙ/βₚ)>1. Since the β values may be considered to be proportional to the device width (assuming the device lengths are equal), it can be seen that the sizes of the PMOS and NMOS devices must be skewed to change the inverter's switching threshold voltage. However, skewing the device sizes to lower the switching threshold voltage for either the rising or falling edge of the input ends up penalizing the other edge by increasing its threshold voltage. Thus, with transfer curve 12, the input voltage high-to-low transitions are faster, but the input voltage low-to-high transitions are slower. Likewise, for curve 14, the low-to-high transitions are faster, but the high-to-low transitions are slower.

Accordingly, there is a need for an integrated circuit design adaptable to provide lower switching threshold voltages for both rising and falling edge input voltages. There is also a need for an inverter design that sharpens the transition of both rising and falling edge signal transitions. In addition, there is need for an improved inverter design which overcomes the problems in the art, such as outlined above.

### BRIEF DESCRIPTION OF THE DRAWINGS

The present invention may be understood, and its numerous objects, features and advantages obtained, when the following detailed description is considered in conjunction with the following drawings, in which:

FIG. 1 depicts transfer characteristic curves for three different CMOS inverter circuits to show how the inverter switching threshold voltage is affected by the changes in the device sizing;

FIG. 2 illustrates in schematic form a first variable switching point inverter circuit in accordance with various selected embodiments of the present invention;

FIG. 3 illustrates the transfer characteristics of the variable switching point inverter circuit of FIG. 2;

FIG. 4 shows voltage-time curves to illustrate how faster inverter switching for both rising and falling edges of the inverter input signal can be obtained by altering the voltage switching point to reduce switching threshold voltages; and

FIG. 5 illustrates in schematic form a second variable switching point inverter circuit in accordance with various selected embodiments of the present invention.

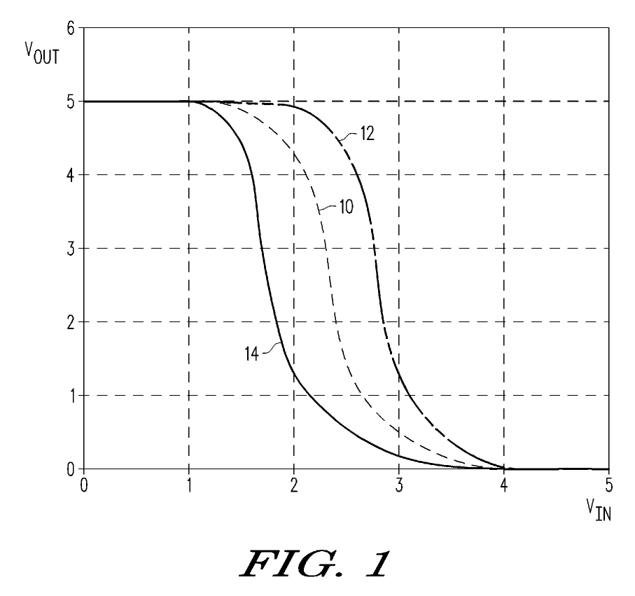

### DETAILED DESCRIPTION

A variable switching point circuit is described in which the threshold voltage is lowered for both rising and falling edge input voltages by changing the P/N ratio of the circuit based on the delayed output state of the circuit. While described with reference to an example inverter circuit, it will be appreciated that various embodiments of the present invention may be implemented with other switching circuits, including but not limited to logic gate circuits, operational amplifier circuits or other circuits whose output depends on the relationship between the input and a threshold voltage. In selected embodiments, the variable switching point inverter is constructed from a first inverter stage coupled in parallel to a second inverter stage having extra PMOS and NMOS transistors connected between respective reference voltages and the output node, where the extra PMOS and NMOS transistors are controlled by the delayed output signal from the first inverter stage. By using a delayed feed back signal to control the extra PMOS and NMOS gates, the threshold voltages of the first inverter stage are altered.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are shown in simplified schematic diagram form, rather than in detail, in order to avoid limiting or obscuring the present invention. Such descriptions and representations are used by those skilled in the art to describe and convey the substance of their work to others skilled in the art.

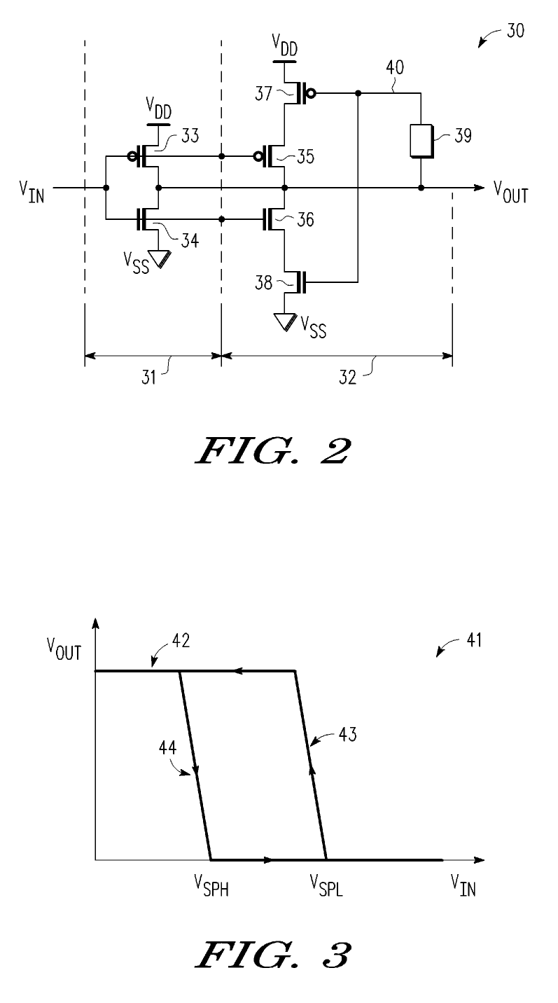

FIG. 2 illustrates in schematic form a first variable switching point inverter circuit 30 in accordance with various selected embodiments of the present invention and FIG. 3 illustrates the transfer characteristic 41 of the variable switching point inverter circuit 30 of FIG. 2. As depicted, the variable switching point inverter circuit 30 may be implemented as a two-stage CMOS inverter having lower threshold voltages for both rising and falling input edges. A first input stage 31 of the circuit 30 is an inverter formed with PMOS and NMOS input devices 33, 34 connected in series between upper and lower reference voltages (e.g., V_{DD} and V_{SS}), where each input device has its gate electrode connected to the circuit input line V_{IN}. A second stage 32 of the circuit 30 is electrically connected to the input stage 31, and includes four MOSFET devices 35-38 series-connected between upper and lower reference voltages (e.g., V_{DD} and V_{SS}). As illustrated, the second stage 32 includes a first pair of the complementary PMOS and NMOS devices 35, 36 that are connected in series, with their common node forming the output V_{OUT} of the inverter circuit 30, and with their gate electrodes electrically connected to the input node V_{IN} through the gate electrodes of the input devices 33, 34, respectively. In addition, the second stage 32 includes a PMOS device 37 that is electrically connected between the PMOS device 35 and an upper reference voltage, and also includes an NMOS device 38 is electrically connected between the NMOS device 36 and a lower reference voltage. The second stage 32 also includes a delay buffer circuit 39 which controls the gate electrodes on the complementary PMOS and NMOS devices 37, 38 by supplying a feedback control signal 40 as a delayed version of the output voltage V_{OUT}.

The first pair of the complementary devices 35, 36 in the second stage 32 are switched ON depending on the level of the V_{IN} signal, and hence the feedback control signal 40, such that they add to the respective input stage inverter devices 33, 34 only one at time. For example, if PMOS device 37 is ON in response to the delayed feedback control signal 40 being LOW, the effective transconductance ratio resulting from PMOS devices 33, 35, 37 and NMOS device 34 being ON provides a higher switch or trip point. This result, in effect, is the addition of a PMOS drive while the NMOS drive (which would be provided by NMOS device 36) is disconnected, and in this circuit, the high-to-low transitions are faster, but the low-to-high transitions are slower. On the other hand, if the NMOS device 38 is ON in response to the delayed feedback control signal 40 being HIGH, the effective transconductance ratio resulting from NMOS devices 34, 36, 38 and PMOS device 33 being ON provides a lower switch or trip point. The resulting effect is to add an NMOS drive while the PMOS drive (which would be provided by PMOS device 35) is disconnected, and in this circuit, the voltage input low-to-high transitions are faster, but the voltage input high-to-low transitions are slower. In this way, the extra PMOS device 37 and NMOS device 38 dynamically alter the threshold voltage of the inverter by changing the ratio of PMOS and NMOS devices.

The operation of the variable switching point inverter circuit 30 is illustrated with the positive hysteresis transfer curve 41 shown in FIG. 3, starting at region 42 where the input voltage V_{IN} has been in a steady state LOW voltage and the output voltage V_{OUT} has been in a steady state HIGH voltage. In this region of the curve 41, the delayed feedback control signal 40 is HIGH, reflecting the fact that the HIGH steady state of the output voltage V_{OUT}. The HIGH delayed feedback control signal 40 turns the PMOS device 37 OFF and turns the NMOS device 38 ON, while at the same time, the LOW input voltage V_{IN} has turned the PMOS device 35 ON and has turned the NMOS device 36 OFF. In effect, the second stage 32 is not influencing the output voltage V_{OUT}. When the input voltage V_{IN} passes the low-to-high switching point voltage (V_{SPH}) and switches to HIGH (indicated at curve 44), the output voltage V_{OUT} goes LOW, abetted by the NMOS devices 36 and 38 which are both ON because the HIGH input voltage V_{IN} turns the NMOS device 36 ON and because the delayed feedback control signal 40 (which is still HIGH) turns the NMOS device 38 ON. The delay buffer circuit 39 should provide sufficient delay to ensure that the output voltage V_{OUT} is pulled LOW by the NMOS devices 36, 38. As will be appreciated, the delay buffer circuit 39 may be formed with one or more delay buffers and/or inverter circuits that provide sufficient delay to the output voltage to prevent the PMOS device 37 from turning ON too quickly, which is not desirable, especially if the PMOS devices 35 and 37 are both ON together. At this point in the operation of the inverter circuit 30 (where the input is transitioning from low-to-high), the trip point V_{SPH} is set by the transconductance ratio of the activated NMOS devices 34, 36, 38 and PMOS device 33 which effectively lowers the trip point V_{SPH} so that the low-to-high input transitions are faster. In addition, the delay provided by the delay buffer circuit is set to ensure that the entire curve segment 44 is achieved during transitions in the input voltage V_{IN} from LOW to HIGH.

Once tripped, the output voltage V_{OUT} goes LOW, causing the delayed feedback control signal 40 to go LOW which turns NMOS device 38 OFF and turns PMOS device 37 ON, thereby raising the high-to-low switching point voltage (V_{SPL}) for subsequent high-to-low input voltage transitions. As a result, when the input voltage V_{IN} again goes LOW at the high-to-low transition (indicated at curve 43), the trip point V_{SPL} is set by the transconductance ratio of the activated PMOS devices 33, 35, 37 and NMOS device 34 so that the high-to-low transitions are faster. By lowering or raising the switching point voltages for input rising edge transition or falling edge transition with respect to the midpoint, the variable switching point inverter circuit 30 provides a positive hysteresis so that the inverter circuit 30 is triggered when the rising input signal crosses the lowered switch point V_{SPH} or when the falling input signal crosses the raised switch point V_{SPL}, such as illustrated in FIG. 3. Thus, the positive hysteresis works in the opposite hysteresis direction of a conventional Schmitt trigger, which uses negative hysteresis, which is triggered when the rising input signal crosses a relatively higher switch point V_{SPH} or when the falling input signal crosses a relatively lower switch point V_{SPL}. In effect, the second stage acts as a threshold voltage control stage to adjust the inverter trip point, depending on whether the input transitions are high-to-low or low-to-high.

The relative values of the low-to-high switch point V_{SPH} and high-to-low switch point V_{SPL} are shown in FIG. 4, which shows voltage-time curves to illustrate how faster inverter switching for both rising and falling edges of the inverter input signal can be obtained by varying the switching point voltages. The upper curve (a) shows a variable input voltage signal 45 that is applied to a variable switching point inverter circuit, while the lower curve (b) shows the resulting inverter output signal 49. As the input signal 45 increases (from LOW to HIGH) above the trip point V_{SPH} (as indicated at node 46), the inverter output 49 changes from HIGH to LOW, but does so more rapidly than with a conventional CMOS inverter because the extra NMOS drive devices (e.g., NMOS 36 and NMOS 38) are pulling the output voltage to V_{SS} for so long as the delay buffer circuit 39 prevents the feedback control signal 40 from turning OFF the NMOS device 38. In this way, the trip point V_{SPH} is set by the transconductance ratio of the activated NMOS devices 34, 36, 38 and PMOS device 33 until the inverter output signal propagates through the delay buffer circuit 39.

As the input signal 45 increases (from LOW to HIGH) above the trip point V_{SPL}, the inverter output 49 remains unchanged, but as the input signal 45 decreases (from HIGH to LOW) below the trip point V_{SPL} (as indicated at node 47), the inverter output 49 changes from LOW to HIGH, again doing so more rapidly than with a conventional CMOS inverter because the extra PMOS drive devices (e.g., PMOS 35 and PMOS 37) are pulling the output voltage to V_{DD} for so long as the delay buffer circuit 39 prevents the feedback control signal 40 from turning OFF the PMOS device 37. Thus, the trip point V_{SPL} for the inverter circuit changes since it is now set by the transconductance ratio of the activated PMOS devices 33, 35, 37 and NMOS device 34 until the inverter output signal propagates through the delay buffer circuit. Finally, while the inverter output 49 remains unchanged as the input signal 45 decreases (from HIGH to LOW) below the trip point V_{SPH}, the inverter output 49 changes from HIGH to LOW as the input signal 45 increases (from LOW to HIGH) above the trip point V_{SPH} (as indicated at node 48).

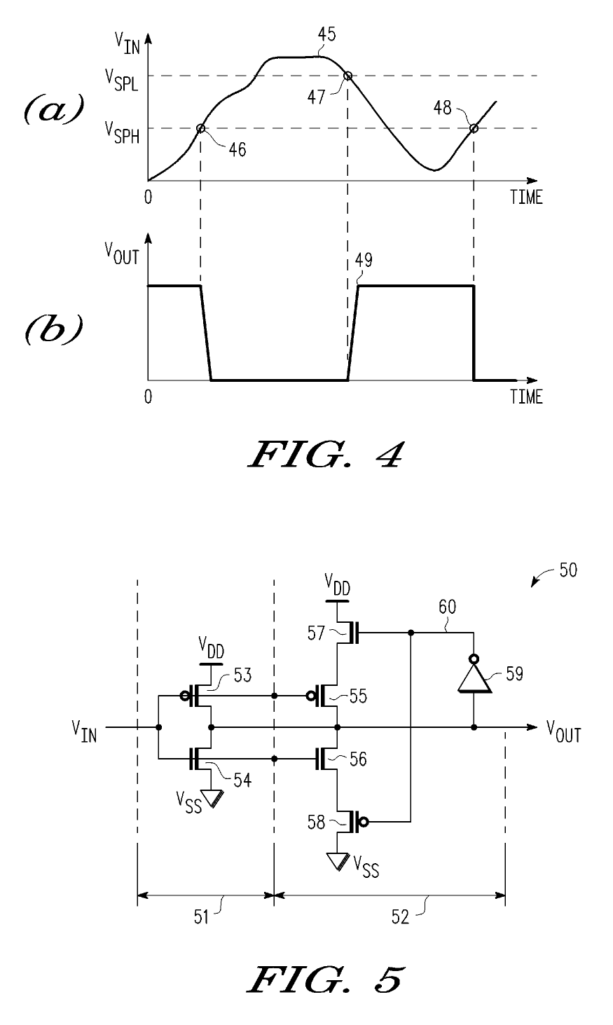

As will be appreciated, other variable switching point inverter circuit designs may be used to alter the switching point of the inverter and obtain lower threshold voltages for both rising and falling edges of the input signal. For example, FIG. 5 illustrates in schematic form a second variable switching point inverter circuit 50 in accordance with various selected embodiments of the present invention. As depicted, the variable switching point inverter circuit 50 is a two-stage CMOS inverter which uses a feedback control signal that is a delayed and inverted version of the inverter output. The first input stage 51 includes PMOS and NMOS input devices 53, 54 connected as an input CMOS inverter between the circuit input line V_{IN} and output line V_{OUT}. The second stage 52 is electrically connected to the first input stage 51, and includes four series-connected MOSFET devices 55-58 connected between upper and lower reference or supply voltages. As illustrated, a first pair of the complementary devices 55, 56 is connected in series, with their common node connected to the output V_{OUT} of the inverter circuit 50, and with their gate electrodes electrically connected to the gate electrodes of the input devices 53, 54, respectively. In addition, complementary NMOS and PMOS devices 57, 58 are electrically connected so that the NMOS device 57 is connected between the drain electrode of the PMOS device 55 and the upper reference voltage (e.g., V_{DD}), while the PMOS device 58 is connected between source electrode of the NMOS device 56 and the lower reference voltage (e.g., V_{SS}). The second stage 52 also includes an inverter delay buffer circuit 59 which controls the gate electrodes on the complementary NMOS and PMOS devices 57, 58 by supplying a feedback control signal 60 as a delayed and inverted version of the output voltage V_{OUT}. The delay buffer circuit 59 should provide sufficient delay to ensure that the output voltage V_{OUT} is pulled LOW by the NMOS device 56 and PMOS device 58 during LOW to HIGH transitions in the input voltage V_{IN}, and may be formed with one or more delay buffers and/or inverter circuits. In addition, the delay provided by inverter circuit 59 prevents the NMOS device 57 from turning ON too quickly, which is not desirable, especially if the PMOS device 55 and NMOS device 57 are both ON together.

In one form, there is provided herein a variable switching point inverter circuit in which a first inverter stage (e.g., a CMOS inverter) receives an input signal at an input node and generates an output signal at an output node. In addition, inverter includes a switching point voltage control stage coupled to the output node to provide a positive hysteresis to the first inverter stage. The switching point voltage control stage also includes a delay circuit that is connected to the output node for generating the delayed output signal that controls the switching point voltage control stage, which in turn dynamically controls a switching point voltage of the first inverter stage. In various embodiments, the switching point voltage control stage may be constructed with a second CMOS inverter stage which is coupled in parallel to the first inverter stage to receive an input signal at a shared input node and to generate an output signal at a shared output node, and which is further coupled in series with additional PMOS and NMOS devices that are controlled by the delayed output signal. For example, by including a first PMOS device that is source-drain connected between the second CMOS inverter stage and a first reference voltage and a first NMOS device that is source-drain connected between the second CMOS inverter stage and a second reference voltage, the delay circuit may be implemented as one or more series-connected buffers to generate a feedback control signal by delaying the output signal, where the feedback control signal is applied to the gate electrodes of the first PMOS and NMOS devices. Alternatively, by including a first NMOS device that is source-drain connected between the second CMOS inverter stage and a first reference voltage and a first PMOS device that is source-drain connected between the second CMOS inverter stage and a second reference voltage, the delay circuit may be implemented as one or more series-connected inverter circuits to generate an feedback control signal by delaying and inverting the output signal, where the feedback control signal is applied to the gate electrodes of the first PMOS and NMOS devices. In this way, the switching point voltage control stage reduces threshold voltage values in the first inverter stage for both low-to-high and high-to-low input signal transitions. In effect, the switching point voltage control stage reduces the threshold voltage of the first inverter stage by adjusting the inverter trip point, depending on whether the input transitions are high-to-low or low-to-high.

In another form, there is provided herein an integrated circuit device having a switching circuit (such as an inverter or an operational amplifier) for generating an output signal in response to receiving an input signal. The switching circuit's operational behavior is defined with reference to a first transfer curve (having a first trip point for rising edge input signal transitions) and a second transfer curve (having a second trip point for falling edge input signal transitions), where the first trip point is less than the second trip point. Together, the first and second transfer curves define a positive hysteresis for the switching circuit. In a selected embodiment, the switching circuit includes a conventional CMOS inverter stage (formed from series-coupled NMOS and PMOS devices), a PMOS drive stage and an NMOS drive stage. The PMOS drive stage is coupled in parallel to the PMOS device in the inverter for selectively coupling the inverter's output node to a first reference voltage (e.g., V_{DD}) during falling edge input signal transitions, while the NMOS drive stage is coupled in parallel to the NMOS device in the inverter for selectively coupling the inverter's output node to the second reference voltage (e.g., V_{SS}) during rising edge input signal transitions. The PMOS drive stage may include a feedback delay circuit connected to the inverter's output node for generating a feedback control signal by delaying the output signal, where the feedback control signal is applied to the gate of a second PMOS device, which in turn is source-drain coupled between the first reference voltage and an additional PMOS drive device which has its source electrode connected to the output node and its gate electrode connected to the inverter's input node. Alternatively, the PMOS drive stage may include a feedback delay circuit connected to the inverter's output node for generating a feedback control signal by delaying and inverting the output signal, where the feedback control signal is applied to the gate of a second NMOS device, which in turn is source-drain coupled between the first reference voltage and an additional PMOS drive device which has its source electrode connected to the output node and its gate electrode connected to the inverter's input node. As will be appreciated, the NMOS drive stage can be implemented with a similar design so long as the device types are reversed as appropriate.

In yet another form, there is disclosed an integrated circuit switching device which includes a first CMOS inverter for receiving and switching an input signal to generate an output signal, and which also includes a drive circuit coupled between the first CMOS inverter and the inverter's output for selectively driving the output node only during rising and falling edge input signal transitions in response to a delayed output signal, thereby providing a positive hysteresis to the first CMOS inverter stage.

Although the described exemplary embodiments disclosed herein are directed to various examples of a variable switching point inverter circuits and methods for using same, the present invention is not necessarily limited to the example embodiments. For example, various embodiments of the variable switching point inverter may be used to form non-inverting buffer circuits by including an additional inverter at the output node. In addition, the variable switching point inverter can advantageously be used as a receiver amplifier for slow edge signals, as a receiver amplifier for clock distribution H-tree and as a receiver for noise-free signals, among other possible applications. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A variable switching point inverter, comprising:
a first inverter stage coupled to receive an input signal at an input node and to generate an output signal at an output node; and
a switching point control stage coupled between the input node and the output node for providing a positive hysteresis to the first inverter stage, thereby dynamically controlling a switching point voltage of the first inverter stage.

2. The inverter of claim 1, where the first inverter stage comprises a PMOS device and an NMOS device coupled in series to form a CMOS inverter.

3. The inverter of claim 1, where the first inverter stage comprises a first PMOS device and a first NMOS device, wherein a gate electrode of each of the first PMOS and NMOS devices is connected to the input node, a drain electrode of the first PMOS device is connected to a first reference voltage, a source electrode of the first NMOS device is connected to a second reference voltage, and source and drain electrodes of the first PMOS and NMOS devices are respectively connected to the output node to form an inverter.

4. The inverter of claim 1, where the switching point control stage comprises:
a second inverter stage coupled in parallel to the first inverter stage to receive an input signal at a shared input node and to generate an output signal at a shared output node;
a feedback delay circuit connected to the shared output node for generating a feedback control signal by delaying the output signal;
a first PMOS device having a drain electrode connected to a first reference voltage, a source electrode connected to the second inverter stage and a gate electrode connected to the feedback control signal; and
a first NMOS device having a source electrode connected to a second reference voltage, a drain electrode connected to the second inverter stage and a gate electrode connected to the feedback control signal.

5. The inverter of claim 1, where the switching point control stage comprises:
a second inverter stage coupled in parallel to the first inverter stage to receive an input signal at a shared input node and to generate an output signal at a shared output node;
a feedback delay circuit connected to the shared output node for generating a feedback control signal by delaying and inverting the output signal;
a first NMOS device having a drain electrode connected to a first reference voltage, a source electrode connected to the second inverter stage and a gate electrode connected to the feedback control signal; and
a first PMOS device having a source electrode connected to a second reference voltage, a drain electrode connected to the second inverter stage and a gate electrode connected to the feedback control signal.

6. The inverter of claim 1, where the switching point control stage comprises a delay circuit connected to the output node for generating the delayed output signal.

7. The inverter of claim 6, where the delay circuit comprises one or more buffers.

8. The inverter of claim 6, where the delay circuit comprises an inverter circuit.

9. The inverter of claim 6, where the delay circuit comprises one or more series connected inverter circuits.

10. The inverter of claim 1, where the switching point control stage reduces threshold voltage values in the first inverter stage for both low-to-high and high-to-low input signal transitions.

11. The inverter of claim 1, where the switching point control stage reduces a threshold voltage of the first inverter stage for both rising and falling edge input signal transitions by raising a high-to-low switching point voltage V_{SPL} and lowering a low-to-high switching point voltage V_{SPH} for the first inverter stage so that V_{SPL} is greater than V_{SPH}.

12. An integrated circuit device comprising a switching circuit for generating an output signal in response to receiving an input signal, where the switching circuit has a first transfer curve defined by a first trip point for rising edge input signal transitions and a second transfer curve defined by a second trip point for falling edge input signal transitions, where the first trip point is less than the second trip point.

13. The integrated circuit device of claim 12, where the switching circuit comprises a logic gate.

14. The integrated circuit device of claim 12, where the switching circuit comprises an operational amplifier.

15. The integrated circuit device of claim 12, where the first and second transfer curves define a positive hysteresis.

16. The integrated circuit device of claim 12, where the switching circuit comprises:
an inverter stage coupled to receive an input signal at an input node and to generate an output signal at an output node, said inverter stage comprising a first PMOS device that is source-drain coupled between a first reference voltage and the output node, and a first NMOS device that is source-drain coupled between the output node and a second reference voltage;
a PMOS drive stage coupled in parallel to the first PMOS device for selectively coupling the output node to the first reference voltage during falling edge input signal transitions; and
an NMOS drive stage coupled in parallel to the first NMOS device for selectively coupling the output node to the second reference voltage during rising edge input signal transitions.

17. The integrated circuit device of claim 16, where the PMOS drive stage comprises:
a feedback delay circuit connected to the output node for generating a feedback control signal by delaying the output signal;
a second PMOS device having a drain electrode, a source electrode connected to the output node and a gate electrode connected to the input node; and
a third PMOS device having a drain electrode connected to the first reference voltage, a source electrode connected to the drain electrode of the second PMOS device and a gate electrode connected to the feedback control signal.

18. The integrated circuit device of claim 16, where the PMOS drive stage comprises:
a feedback delay circuit connected to the output node for generating a feedback control signal by delaying and inverting the output signal;
a second PMOS device having a drain electrode, a source electrode connected to the output node and a gate electrode connected to the input node; and
a second NMOS device having a drain electrode connected to the first reference voltage, a source electrode connected to the drain electrode of the second PMOS device and a gate electrode connected to the feedback control signal.

19. An integrated circuit switching device, comprising:
a CMOS inverter circuit for receiving an input signal at an input node and switching the input signal to generate an output signal at an output node; and
a drive circuit coupled between the input node and the output node of the CMOS inverter circuit for selectively driving the output node only during rising and falling edge input signal transitions in response to a delayed output signal.

20. The integrated circuit switching device of claim 19, where the drive circuit provides a positive hysteresis to the CMOS inverter circuit.
